(19) United States
(12) Patent Application Publication
(10) Pub. No.: US 2008/0136548 A1
(43) Pub. Date: Jun. 12, 2008

(54) IMPEDANCE MATCHING DEVICE OF SENSOR NODE AND IMPEDANCE MATCHING METHOD OF SENSOR NODE

(75) Inventors: Juderk PARK, Daejeon-city (KR); Nae-soo Kim, Daejeon-city (KR); Cheol Sig Pyo, Daejeon-city (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejeon-city (KR)

(21) Appl. No.: 11/860,388

(22) Filed: Sep. 24, 2007

(30) Foreign Application Priority Data
Dec. 8, 2006 (KR) 10-2006-0125052

(51) Int. Cl. H03H 7/38

(52) U.S. Cl. 333/17.3

(57) ABSTRACT

Provided are an impedance matching device of a sensor node and an impedance matching method of a sensor node. The impedance matching device comprises: a variable impedance matching unit disposed between a transmission unit, which is used for modulating a received signal to a radio frequency (RF) signal and outputting the RF signal, and an antenna and including a plurality of impedance matching circuits which have different impedance values from each other; a signal intensity measuring unit which measures the intensity of an output signal that is output through the variable impedance matching unit; and a control unit which controls one of the impedance matching circuits of the variable impedance matching unit to have an impedance value that maximizes the intensity of the output signal. Accordingly, impedance between the transmission unit and the antenna of the sensor node is adjusted when the impedance varies due to the environment in which the sensor node is used, and thus the transmission efficiency of the sensor node is improved. Consequently, a limited power source of the sensor node can be used for a longer duration, the sensor node can be connected to other sensor nodes more successfully, and the communication reliability of the sensor node can be secured.

### CROSS-REFERENCE TO RELATED PATENT APPLICATIONS

This application claims the priority of Korean Patent Application No. 10-2006-0125052, filed on Dec. 8, 2006, in the Korean Intellectual Property Office, the disclosure of which is incorporated herein in its entirety by reference.

### BACKGROUND OF THE INVENTION

1. Field of the Invention

The present invention relates to an impedance matching device of a sensor node and an impedance matching method of a sensor node, and more particularly, to an impedance matching device of a sensor node and an impedance matching method of a sensor node for a wireless sensor network, which improve the radio frequency transmission efficiency of the sensor node.

2. Description of the Related Art

As wireless network technology has developed, the range and frequency of applications of mobile wireless computing have rapidly increased.

In a mobile wireless computing network, nodes have to be able to transmit data between each other, a data transmission range is limited due to a limited power source, bandwidth is low and the error rate is high.

Despite these disadvantages, mobile wireless computing networks can be used in such places as battlefields or exhibition centers where no fundamental communication network is established.

For a sensor node which is used for disaster rescue, bushfire monitoring, wartime operations, and so on, it is costly or impossible to change the internal power source when the sensor node is used in practice. Such sensor nodes can be used only for a limited duration equivalent to the lifetime of the internal power source which is mounted before the sensor node is actually used.

Thus, impedance matching between a transmission unit and an antenna of the sensor node has to be achieved in order to radiate necessary radio frequencies using the antenna by efficiently using the limited internal power source of the sensor node.

In general, a sensor node for a wireless sensor network (WSN) is formed of a single chip including a modem, a radio frequency (RF) circuit, and an impedance matching circuit, and has a fixed impedance value. Thus, an antenna of the sensor node is designed for the fixed impedance value of the chip.

However, when the sensor node is used in practice, the sensor node is affected by the angle of the antenna and the electrical characteristics of peripheral objects, and thus the resonant frequency of the antenna may vary.

That is, the impedance value of the antenna is changed, and consequently the impedance between the transmission unit and the antenna is not matched, which leads to reduced transmission efficiency.

In the WSN, the sensor node used secures a communication channel through connection between equivalent devices using an ad-hoc communication method, and therefore there is no additional device such as a base station that controls the communication sensitivity.

The disadvantage of the sensor node, that is, reduced communication performance due to the variation of the impedance value according to the environment in which the sensor node is used, needs to be resolved.

### SUMMARY OF THE INVENTION

The present invention provides an impedance matching device of a sensor node and an impedance matching method of a sensor node, which enhance the transmission efficiency of the sensor node by adjusting the impedance between a transmission unit and an antenna of the sensor node.

According to an aspect of the present invention, there is provided an impedance matching device of a sensor node, the impedance matching device comprising; a variable impedance matching unit disposed between a transmission unit, which is used for modulating a received signal to a radio frequency (RF) signal and outputting the RF signal, and an antenna and comprising a plurality of impedance matching circuits which have different impedance values to each other; a signal intensity measuring unit which measures the intensity of an output signal that is output through the variable impedance matching unit; and a control unit which controls one of the impedance matching circuits of the variable impedance matching unit to have an impedance value that maximizes the intensity of the output signal.

According to another aspect of the present invention, there is provided an impedance matching method of a sensor node, the impedance matching method comprising: selecting an impedance matching circuit that has a specific impedance value from among a plurality of impedance matching circuits by using a switch; measuring the intensity of an output signal output from the selected impedance matching circuit; and selecting the impedance matching circuit which has an impedance value that maximizes the intensity of the output signal.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a sensor node for a general wireless sensor network (WSN);

FIG. 2A is a block diagram of an impedance matching device of a sensor node, according to an embodiment of the present invention;

FIG. 2B is a block diagram of a sensor node employing the impedance matching device illustrated in FIG. 2A, according to an embodiment of the present invention; and

FIG. 3 is a flowchart illustrating a method of impedance matching of a sensor node, according to an embodiment of the present invention.

### DETAILED DESCRIPTION OF THE INVENTION

Generally, since the impedance of the transmission unit of the sensor node is fixed based on a structure of a chip, the impedance between the transmission unit and the antenna is required to be adjusted. According to the present invention, the signal intensity measuring unit is included in order to measure the intensity of an output signal which is output from the transmission unit of the sensor node, the impedance value between the transmission unit and the antenna is adjusted so that the output signal can be maximized, and thus, the transmission efficiency of the sensor node is improved.

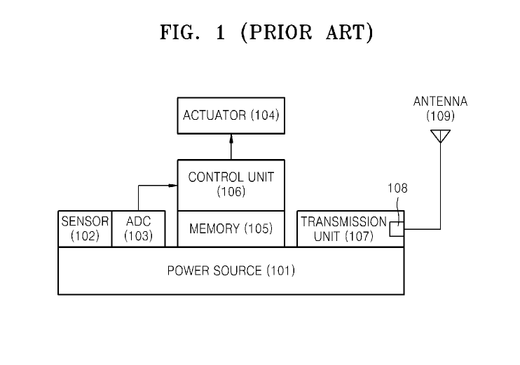

FIG. 1 is a block diagram of a conventional sensor node for a general wireless sensor network (WSN). Referring to FIG. 1, the sensor node includes a power source 101, a sensor 102, an analog-to-digital converter (ADC) 103, an actuator 104, a memory 105, a control unit 106, a transmission unit 107, a fixed impedance matching unit 108, and an antenna 109.

The power source 101 supplies a constant voltage to the sensor node. The power source 101 inside the sensor node supplies the constant voltage to each element of the sensor node to operate.

The sensor 102 collects information.

The ADC 103 converts an analog signal to a digital signal.

The actuator 104 performs an operation in response to a command from the control unit 106.

The memory 105 is an internal memory device of the sensor node. The program for executing commands is stored in the memory 105.

The control unit 106 is a processor for issuing and controlling commands and may be a microprocessor.

In general, in the sensor node, the sensor 102 collects information about the temperature, humidity, and brightness of the surroundings, and the ADC 103 converts the relevant information to digital signals and transmits the digital signals to the control unit 106. The control unit 106 transmits a control signal to the actuator 104.

When the sensor node communicates with another sensor node, the transmission unit 107 modulates the signals and radiates radio frequencies through the antenna 109.

The fixed impedance matching unit 108 for impedance matching between the transmission unit 107 and the antenna 109 may be disposed in the transmission unit 107.

The fixed impedance matching unit 108 includes a fixed impedance matching circuit. Generally, the impedance of the transmission unit 107 is fixed according to the chip structure of the transmission unit 107.

The transmission unit 107 is formed as a single chip which includes a modem, a radio frequency (RF) circuit, and the fixed impedance matching unit 108, and has a fixed impedance value.

Thus, the antenna 109 is designed for the fixed impedance value of the transmission unit 107 and is mounted to the sensor node.

However, when the sensor node is used in practice, the sensor node is affected by the angle of the antenna 109 and the electrical characteristics of peripheral devices, and thus the resonant frequency of the antenna 109 is changed.

Due to the change of the resonant frequency of the antenna 109, the impedance value of the antenna 109 is changed, which leads to mismatching of impedances between the transmission unit 108 and the antenna 109, and thus the transmission efficiency of the sensor node is deteriorated.

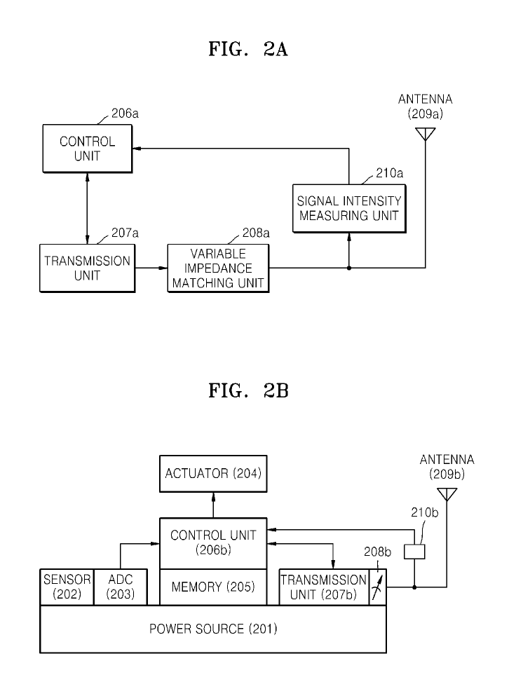

FIG. 2A is a block diagram of an impedance matching device of a sensor node, according to an embodiment of the present invention. Referring to FIG. 2A, the impedance matching device according to the current embodiment of the present invention includes a control unit 206a, a transmission unit 207a, a variable impedance matching unit 208a, an antenna 209a, and a signal intensity measuring unit 210a.

The variable impedance matching unit 208a can adjust the impedance between the transmission unit 207a and the antenna 209a.

The signal intensity measuring unit 210a measures the intensity of the electromagnetic field of an output signal that is output via the variable impedance matching unit 208a, and transmits the value of the measured intensity to the control unit 206a.

The variable impedance matching unit 208a may include a plurality of impedance matching circuits that have different impedance values. The variable impedance matching unit 208a selects an impedance matching circuit that has a specific impedance value from among the plurality of impedance matching circuits by using a switch.

The control unit 206a stores output signals produced via the plurality of impedance matching circuits that have different impedance values.

The control unit 206a outputs a radio frequency (RF) signal using an impedance matching circuit of the variable impedance matching unit 208a, the impedance matching circuit having an impedance value which maximizes the intensity of the output signal.

As such, according to an embodiment of the present invention, the signal intensity measuring unit 210a measures the intensity of the signal output from the transmission unit 207a while the impedance value of the variable impedance matching unit 208a is adjusted, and the impedance value of the variable impedance matching unit 208a is changed to the impedance value that maximizes the intensity of the output signal, thereby enhancing the transmission efficiency of the sensor node.

FIG. 2B is a block diagram of a sensor node employing the impedance matching device illustrated in FIG. 2A, according to an embodiment of the present invention. Referring to FIG. 2B, like the conventional sensor node for a WSN as illustrated in FIG. 1, the sensor node according to the current embodiment of the present invention includes a power supply 201, a sensor 202, an analog-to-digital converter (ADC) 203, an actuator 204, a memory 205, a control unit 206, a transmission unit 207, and an antenna 209.

However, the sensor node according to the present embodiment has a variable impedance matching unit 208b instead of the fixed impedance matching unit 108 of the sensor node for a WSN illustrated in FIG. 1, and further includes a signal intensity measuring unit 210b.

The sensor node measures the intensity of an output signal output from the transmission unit 207b using the signal intensity measuring unit 210b while adjusting the impedance value of the variable impedance matching unit 208b. The intensity of the electromagnetic field of the output signal may be measured as the intensity of the output signal.

The control unit 206b controls the variable impedance matching unit 208b to have an impedance value that maximizes the intensity of the output signal.

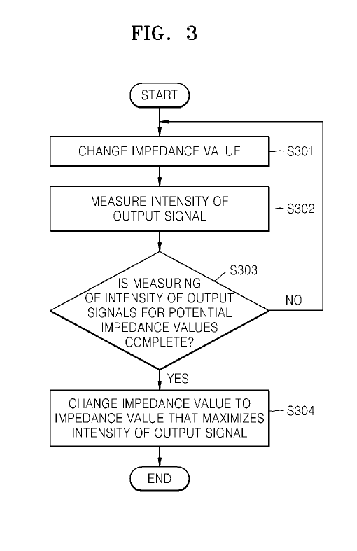

FIG. 3 is a flowchart illustrating a method of impedance matching of a sensor node, according to an embodiment of the present invention.

An impedance matching circuit that has a specific impedance value is selected from among a plurality of impedance matching circuits which have different impedance values, an impedance value is changed to the impedance value of the selected impedance matching circuit (S301), and the intensity of an output signal is measured (S302). The impedance matching circuit may be selected by a switch.

The intensity of the output signal is repeatedly measured for all possible impedance values, i.e. for each of the plurality of impedance matching circuits (S303).

An impedance value is controlled to the impedance value of the impedance matching circuit, which has the impedance value that maximizes the intensity of the output signal (S304).

As described above, according to the present invention, the intensity of an output signal output from a transmission unit of a sensor node is measured using a signal intensity measuring unit while an impedance value of a variable impedance matching unit of the sensor node is adjusted, and the impedance value of the variable impedance matching unit is changed to the value that maximizes the intensity of the output signal, thereby enhancing the transmission efficiency of the sensor node.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion.

According to the present invention, impedance between a transmission unit and an antenna of a sensor node is adjusted when the impedance varies due to the environment in which the sensor node is used, and thus the transmission efficiency of the sensor node is improved. Accordingly, a limited power source of the sensor node can be used for a longer duration, the sensor node can be connected to other sensor nodes more successfully, and the communication reliability of the sensor node is secured.

In particular, the deterioration of communication quality can be solved when the deterioration is caused by impedance mismatching between an antenna and a transmission unit of a sensor node when the sensor node is operated with limited power.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An impedance matching device of a sensor node, the impedance matching device comprising;
a variable impedance matching unit disposed between a transmission unit, which is used for modulating a transmitting signal to a radio frequency (RF) signal and outputting the RF signal, and an antenna and comprising a plurality of impedance matching circuits which have different impedance values to each other;
a signal intensity measuring unit which measures the intensity of an output signal that is output through the variable impedance matching unit; and
a control unit which controls one of the impedance matching circuits of the variable impedance matching unit to have an impedance value that maximizes the intensity of the output signal.

2. The impedance matching device of claim 1, wherein the control unit determines the impedance value that maximizes the intensity of the output signal based on the intensity of each of a plurality of output signals which are output from the plurality of impedance matching circuits that have different impedance values.

3. The impedance matching device of claim 1, wherein the intensity of the output signal corresponds to the intensity of an electromagnetic field of the output signal.

4. The impedance matching device of claim 1, wherein the variable impedance matching unit selects an impedance matching circuit that has a specific impedance value from among the plurality of impedance matching circuits by using a switch.

5. An impedance matching method of a sensor node, the impedance matching method comprising:
selecting an impedance matching circuit that has a specific impedance value from among a plurality of impedance matching circuits by using a switch;
measuring the intensity of an output signal output from the selected impedance matching circuit; and
selecting the impedance matching circuit which has an impedance value that maximizes the intensity of the output signal.

6. The impedance matching method of claim 5, wherein the intensity of the output signal corresponds to the intensity of an electromagnetic field of the output signal.

7. A computer readable recording medium having embodied thereon a computer program for executing a method claimed in claim 6.

8. A computer readable recording medium having embodied thereon a computer program for executing a method claimed in claim 5.
